(19) United States
(12) Patent Application Publication
(10) Pub. No.: US 2024/0106082 A1
(43) Pub. Date: Mar. 28, 2024

(54) Method for Producing a Cell-Contacting System, Electrical Energy Store and Motor Vehicle

(71) Applicant: Bayerische Motoren Werke Aktiengesellschaft, Muenchen (DE)

(72) Inventor: Torsten FRANKE, Muenchen (DE)

(21) Appl. No.: 18/270,323

(22) PCT Filed: Feb. 25, 2022
(86) PCT No.: PCT/EP2022/054771

§ 371 Date: Jun. 29, 2023

(30) Foreign Application Priority Data
Mar. 22, 2021 (DE) 10 2021 106 943.2

(51) Int. Cl. H01M 50/519; H01M 10/42; H01M 10/613; H01M 50/238; H01M 50/249

(52) U.S. Cl. CPC H01M 50/519; H01M 10/425; H01M 10/613; H01M 50/238; H01M 50/249; H01M 2220/20

(57) ABSTRACT

A method for producing a cell-contacting system for a cell assembly of energy storage cells includes creating a first part of a conductive pattern for connecting the energy storage cells by structuring of a conductive material that involves cutting out holes from the conductive material; integrating the structured conductive material into an electrically insulating substrate by joining through primary forming of an insulating material, wherein the insulating material is arranged at least locally at the holes for mechanically connecting conductive tracks of the conductive pattern, and wherein the insulating material has access openings for exposing conductive track portions serving as cell contacts, and for creating a second part of the conductive pattern; and creating the second part of the conductive pattern by further structuring of the conductive material.

### BACKGROUND AND SUMMARY OF THE INVENTION

The invention relates to a method for producing a cell-contacting system for a cell assembly of energy storage cells of an electrical energy store. The invention further relates to an electrical energy store, and to a motor vehicle.

The focus of the present document is electrical energy stores which can be employed, for example, as traction batteries for electrified motor vehicles, i.e. electric or hybrid vehicles. Electrical energy stores of this type customarily comprise at least one cell assembly of a plurality of energy storage cells. For the interconnection of energy storage cells, a cell-contacting system is employed. The cell-contacting system customarily comprises intercell connectors, which are provided in the form of individual sheet metal elements arranged in an electrically insulating carrier. These sheet metal elements are connected by bonding wires to cell terminals of the energy storage cells. In a cell-contacting system of this type, the multipart structure is disadvantageous, as are the limited rigidity and strength of the arrangement comprised of a cell assembly and a cell-contacting system. On the grounds of its multipart structure, the cell-contacting system is associated with a high complexity of production and high costs.

The object of the present invention is the provision of a solution, by way of which a cell-contacting system can be produced in a simple and cost-effective manner.

According to the invention, this object is fulfilled by a method, by an electrical energy store, and by a motor vehicle having features according to the respective independent patent claims.

A method according to embodiments of the invention is employed for producing a cell-contacting system for a cell assembly of energy storage cells of an electrical energy store. In a first step, a first part of a conductive pattern for the interconnection of energy storage cells is formed by the structuring of a conductive material, wherein this structuring involves the extraction of cut-outs from the conductive material. In a second step, the structured conductive material is integrated in an electrically insulating carrier by way of joining, which is achieved by the primary forming of an insulating material, wherein the insulating material, for the purpose of mechanically connecting conductor tracks, is arranged at least locally in the cut-outs, and wherein access openings are formed in the insulating material for the exposure of conductor track sections serving as cell contacts, and for the configuration of at least one second part of the conductive pattern. In a third step, at least one second part of the layout of conductor tracks is formed by the structuring of the conductive material, wherein further cut-outs are extracted from the conductive material via the access openings in the insulating material.

The invention further relates to an electrical energy store having at least one assembly of energy storage cells, a store housing and at least one cell-contacting system, which is produced by way of a method according to embodiments of the invention, wherein the at least one cell assembly and the at least one cell-contacting system are arranged in an interior housing space of the store housing, and wherein the cell contacts are electrically connected to cell terminals of the energy storage cells. The electrical energy store can be, for example, a high-voltage energy store, which is employed as a rechargeable traction battery or traction accumulator for an electrically powered motor vehicle. The electrical energy store comprises the at least one cell assembly, which comprises a plurality of energy storage cells. The energy storage cells can be configured, for example, in the form of prismatic energy storage cells or pouch cells. Energy storage cells are preferably configured in the form of cylindrical cells. The energy storage cells comprise cell terminals or cell poles. A first cell terminal can be configured, for example, on a cell housing cover of a cell housing of the energy storage cells. A second cell terminal can be configured, for example, in the form of an electrically conductive and metallic lower housing part, which is electrically insulated from the cell housing cover and which comprises a cell housing base and cell housing sidewalls.

For the interconnection of energy storage cells, a cell-contacting system is provided. The cell-contacting system is arranged on that side of the cell assembly on which the cell terminals are located. By way of cell terminals on the cell housing cover, the cell-contacting system is arranged on an upper side of the cell assembly which is formed by the cell housing cover. The cell-contacting system comprises conductor tracks, which comprise conductor track sections in the form of cell contacts and connections. The conductive pattern or conductive layout is formed in accordance with a predefined and intentional interconnection of energy storage cells, such that cell contacts can be mutually electrically connected, in a selective manner, with individual cell terminals of the energy storage cells, and via the connections. The cell-contacting system is formed by an alternating series of structuring and primary forming process steps. Firstly, a conductive material is provided, for example in the form of sheet metal. In a first step, cut-outs are extracted from this conductive material, particularly by stamping. The selection of cut-outs is executed such that the remaining conductive material regions are mechanically, but also electrically connected, such that the conductive material retains its one-piece form. These remaining conductive material regions form the first part of the conductive pattern. The conductive pattern formed by cut-outs is also described as a leadframe or die-punched comb.

The structured conductive material is now integrated in the carrier. To this end, in a second step, the structured conductive material is joined to the insulating material by way of primary forming. The insulating material is a stabilizing and electrically insulating material, for example a plastic. By primary forming, the amorphous insulating material is used to produce a solid carrier having a geometrically defined form. To this end, for example, the insulating material is plasticized, molded and cured. During primary forming, the structured conductive material is embedded in the insulating material, and is thus mechanically bonded to the insulating material. A bonding technique of this type for joining by primary forming can comprise, for example, the over-molding or casting of the structured conductive material in the insulating material. During primary forming, in particular, the cut-outs in the structured conductor material are at least locally covered by the insulating material. By using the insulating material, the remaining conductive material regions can be mechanically interconnected. The insulating material can be applied to both sides of the structured conductive material. Moreover, surface profiles or vertical profiles on the carrier can be formed during the primary forming of the insulating material. Different surface profiles may be applied to the underside and the upper side of the conductive material. The surface profile includes, for example, access openings via which the energy storage cells, by the arrangement of the cell-contacting system on the cell assembly, can be contact-connected with those conductor track sections which form the cell contacts. Moreover, the access openings are employed for the further structuring of the conductor material in a third step.

In this third step, further cut-outs are extracted from the conductive material via the access openings. In particular, those regions associated with the configuration or production of the conductive pattern are cut out which, in the first step, it would not have been possible to cut out, as this would otherwise have resulted in a multi-piece conductor track layout comprised of individual parts, in which an unwanted electrical connection of conductive material regions would nevertheless have been formed. Further to this third step, the conductive pattern can be completed. It may be the case, however, depending upon the complexity of the conductive pattern, that further second and third steps are executed.

By way of a method of this type, which comprises structuring, particularly stamping, and primary forming, for example over-molding, a cost-effective cell-contacting system can be produced in a simple manner, having a conductive pattern with a high degree of complexity.

It can be provided that the conductor track sections which form the cell contacts emanate from the carrier in a stepped arrangement, and form a planar, leaf spring-like contact surface. In the conducive material, a step is thus formed by bending in the region of the access openings, wherein an end section of the conductor track forms the planar contact surface, which can be arranged in full-surface contact with the cell terminals. Moreover, by the structuring of the conductive material, conductor track sections can be produced which are configured in the form of power terminals for the contact-connection of the cell assembly and/or in the form of sensor terminals for the contact-connection of sensors of the electrical energy store and/or in the form of cell connectors for the connection of cell contacts and/or as tapers for the formation of a fusible link and/or in the form of pin-type contact elements which are connected to the cell contacts. Conductor tracks can also be integrated in the conductive pattern, for example for the feedthrough of conductors between a rear end and a front end of a motor vehicle for the connection of drive units and/or auxiliary units.

It has proved to be advantageous that, during the primary forming of the insulating material, wall regions are formed for the production of locators for the energy storage cells and/or locators for reinforcement elements and/or insulating coverings for conductor track sections and/or latching elements of the carrier. The surface profile of the underside of the carrier, which faces the cell assembly, is thus configured to form locators for the energy storage cells. These locators are comprised of wall regions which, at least partially, extend in a vertical direction of the energy storage cells beyond the cell housing side walls. In the case of cylindrical cells, the locators can assume, for example, a cylindrical shape or a honeycomb shape. In the wall regions, thickenings can be configured which form localized tapers of the locator, such that the energy storage cells are securely clamped in the locators. Insulating coverings can be formed, for example, on the upper side of the carrier. Moreover, locators can be provided for reinforcement elements which are arranged, for example, in the wall regions. Locators can be, for example, through-openings, into which reinforcement elements in the form of struts are introduced. Latching elements can engage, for example, with corresponding latching elements on the cell housings of the energy storage cells, thus securing the energy storage cells. Latching elements can also engage with other elements, for example force transmission elements.

In a further development of the method, at least one bending edge is configured in the carrier such that, during the primary forming of the insulating material, line-shaped material recesses are formed in the carrier wherein, by way of the at least one bending edge, at least one edge region of the cell-contacting system is folded to form a frame which at least partially encloses the cell assembly. For example, the carrier can be configured with a rectangular shape, wherein the edge regions are foldable on all sides. The folded edge regions can also comprise conductor track sections. For example, one of the edge regions can comprise power terminals for the contact-connection of the cell assembly, such that power terminals are arranged laterally to the cell assembly.

In one configuration of the electrical energy store, a housing part which faces the cell-contracting system comprises at least one camber, which is designed to compress the cell contacts against the cell terminals of the energy storage cells. The store housing can comprise housing parts in the form of a housing cover or upper housing part, and a housing base or lower housing part, which are combined to form the housing interior. One of the housing parts, for example the housing cover, can comprise the at least one camber, which engages with the cell-contacting system such that the cell contacts are compressed against the cell terminals. The at least one camber thus forms a pressure contact. The camber can be configured, for example, with an anvil shape, and thus applies pressure to the planar contact surface of the cell contacts.

It can also be provided that the housing cover and the housing base of the store housing are configured with a double-walled design, for the conduction of a coolant. The at least one cell assembly can thus be cooled on two sides. This embodiment, in combination with the at least one camber which forms the pressure contact, is particularly advantageous on the grounds that, in this case, each of the double-walled housing parts is arranged in proximity to the at least one cell assembly, such that the throughflow of coolant can evacuate waste heat from the energy storage cells.

In a further development, the electrical energy store comprises a monitoring device, which is arranged on the carrier on a side of the cell-contacting system which is averted from the cell assembly and which is designed, for the monitoring of energy storage cells, to transmit signals between sensor devices of the energy storage cells and at least one control device of the electrical energy store. It can be provided that the monitoring device comprises a waveguide for the transmission of acoustic and/or optical signals, wherein the waveguide is configured in the form of a one-piece or multi-piece molding. A side of the monitoring device which faces the cell-contacting system can comprise guide elements for pressure contact pins, for the compression of cell contacts against the cell terminals. The molding is designed to couple at least one sensor device to at least one control device of the electrical energy store in a potential-free arrangement. To this end, in a particular embodiment, the molding comprises at least one bus duct for connection to the control device, and connecting channels, which are connected thereto, for connection to the sensor devices of the energy storage cells, and is thus a finished part, which can be fitted to the energy storage cells and the control device with just one assembly step. In this form, accordingly, the molding is not comprised of individual components which need to be connected or wired together, but forms an integral transmission system, for example a bus system, for signal transmission. The molding can comprise flexible regions, such that it can be folded in combination with the cell-contacting system.

The invention moreover includes a motor vehicle having at least one electrical energy store according to embodiments of the invention. The motor vehicle is particularly configured as an electrically powered motor vehicle, in the form of a passenger motor vehicle.

Embodiments proposed with respect to the method according to the invention, and the advantages thereof, apply correspondingly to the electrical energy store according to embodiments of the invention and to the motor vehicle according to embodiments of the invention.

Further features of the invention proceed from the claims, the figures and the description of the figures. The features and combinations of features described above, and the individual features and combinations of features specified hereinafter in the description of the figures and/or represented in the figures, are not only applicable in the respective combination indicated, but also in other combinations, or in isolation.

The invention is described in greater detail hereinafter on the basis of a preferred exemplary embodiment, and with reference to the drawings.

### BRIEF DESCRIPTION OF THE DRAWINGS

FIGS. 1a-1d show process steps for the production of one embodiment of a cell-contacting system.

FIG. 2 shows a schematic representation of a cell-contacting system, having a finished conductor track layout.

FIG. 3 shows a schematic representation of a carrier of the cell-contacting system.

FIG. 4 shows a schematic section of one embodiment of an electrical energy store, having a cell-contacting system.

FIG. 5 shows a schematic lateral sectional representation of a further embodiment of an electrical energy store.

FIG. 6 shows a schematic sectional representation of a further embodiment of an electrical energy store.

FIG. 7 shows a schematic representation of the cell-contacting system, with one embodiment of a monitoring device.

FIGS. 8a and 8b show schematic sectional representations of the carrier, with energy storage cells.

### DETAILED DESCRIPTION OF THE DRAWINGS

In the figures, identical or functionally equivalent elements are identified by the same reference symbols.

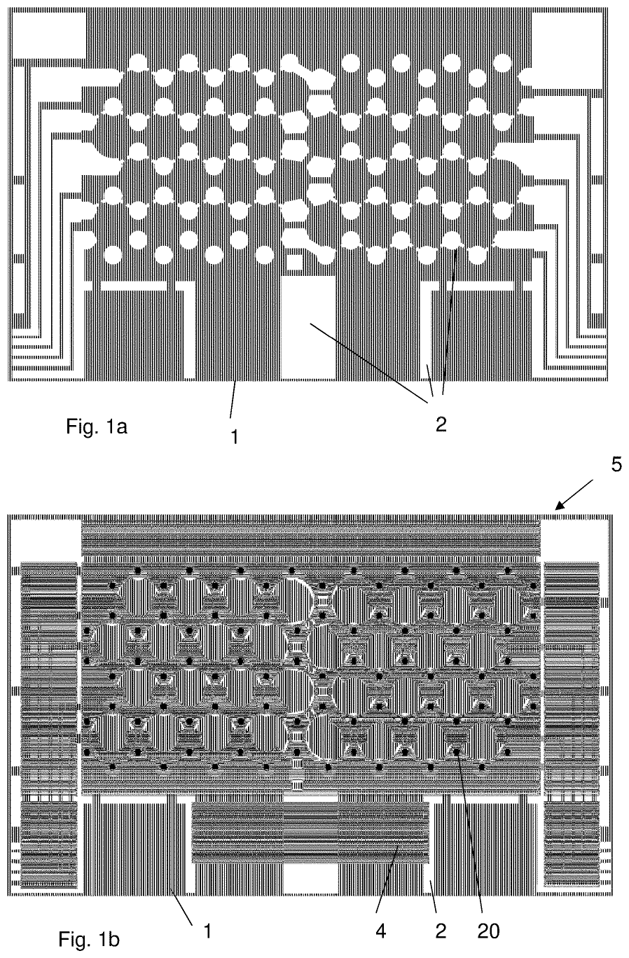

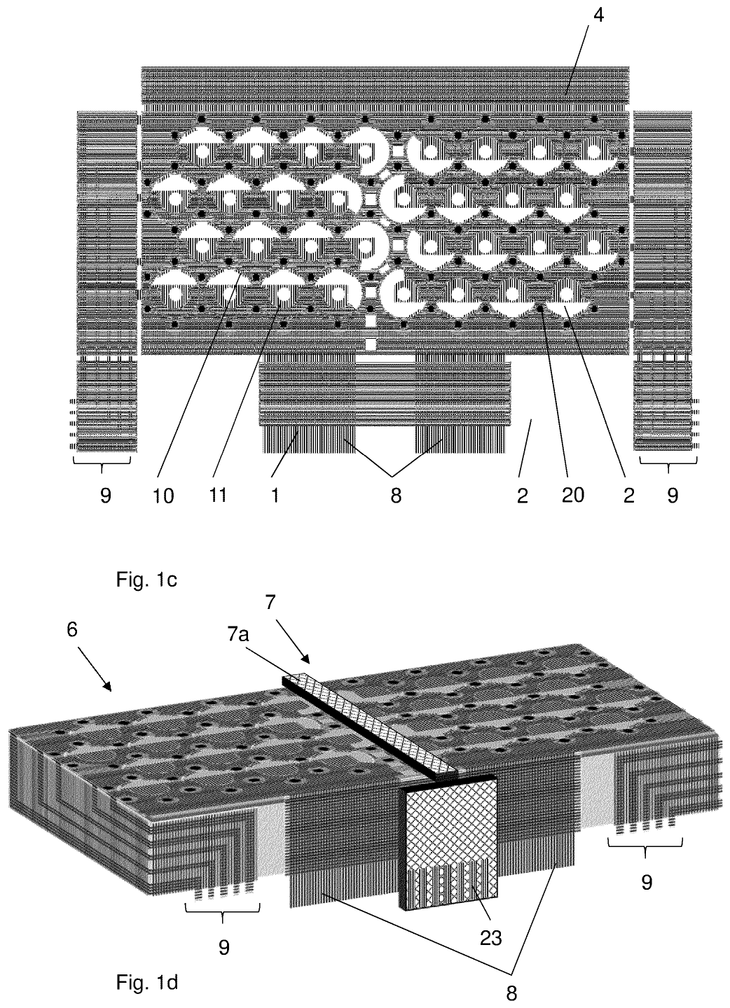

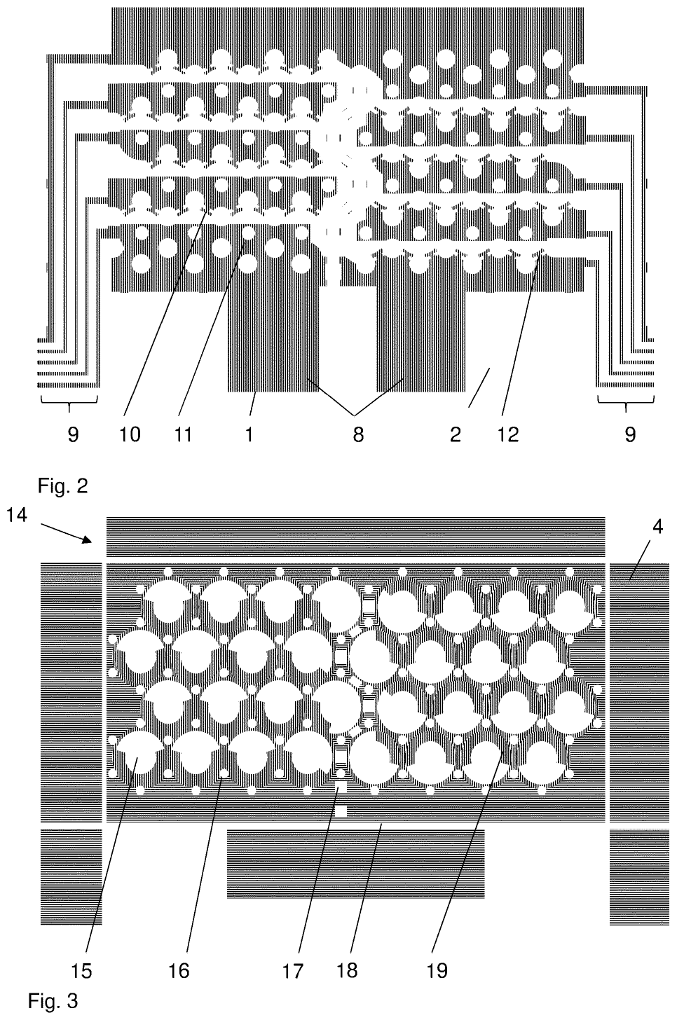

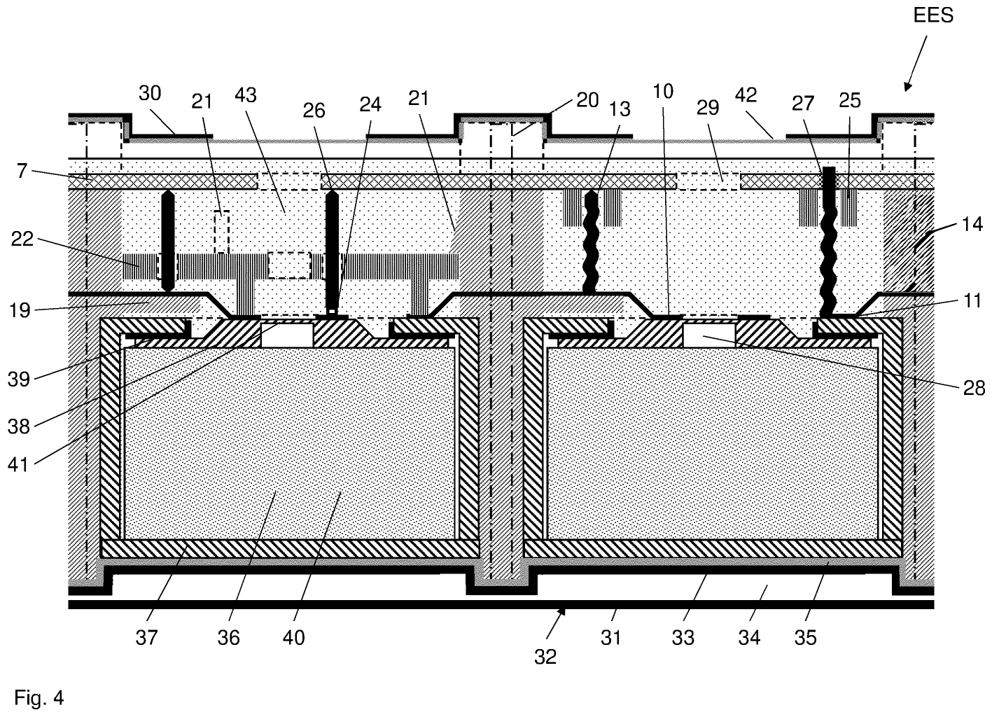

FIGS. 1a to 1d show process steps for the production of a cell-contacting system 6, of which one embodiment is represented in FIG. 1d. The cell-contacting system 6 is employed for the interconnection of energy storage cells 36 (see FIG. 4) of an electrical energy store EES, to form at least one cell assembly. The electrical energy store EES can be employed, for example, as a traction battery for an electrified motor vehicle. For the production of the cell-contacting system 6, as represented in FIG. 1a, a conductive material 1, for example in the form of sheet metal, is provided and structured. To this end, insulating cut-outs 2 are extracted from the conductive material 1 to form a first part of a functional conductive pattern 3 or conductor track layout (see FIG. 2). Insulating cut-outs 2 are at least incorporated in all those regions which, in a second production step represented in FIG. 1b, are covered by a stabilizing insulating material 4. Insulating cut-outs 2 are restricted such that the dimensional relationship of all regions which are comprised of the conductive material 1 is maintained. In particular, a further requirement applies to the insulating cut-outs 2, in that the latter are required to provide a sufficient material connection for the stabilizing insulating material 4 which is applied on both sides, thus providing a high degree of stability of the assembly 5 in response to shear forces.

In a third process step, which is represented in FIG. 1c, further insulating cut-outs 2 are incorporated in those regions which are not covered by the insulating material 4, which form access openings for the production of a second part of the conductive pattern 3, in order to complete the conductive pattern 3. In the event of particular requirements for the conductive pattern 3, the production sequence can be expanded to include further production steps according to FIG. 1b and FIG. 1c. In an optional fourth process step according to FIG. 1d, the planar assembly 5 is folded to produce the finished cell-contacting system 6. A monitoring device 7 can be fitted to the cell-contacting system 6, which is configured here in the form of a senseboard 7a.

The exemplary functional conductive pattern 3 represented in FIG. 2, which is produced by the at least two-fold structuring of the conductive material 1, comprises conductor track sections, which function as power terminals 8 for the contact-connection of the cell assembly comprised of interconnected energy storage cells 36, sensor terminals 9, partially interconnected first cell contacts 10 and second cell contacts 11, a fusible link configured by way of tapers 12 in the conductor tracks, and pin-type contact elements 13 or prepared contacts. Prepared contacts 13 can be formed, for example, during the first production step according to FIG. 1a, the third production step according to FIG. 1c, or the fourth production step according to FIG. 1d.

The stabilizing insulating material 4 forms a carrier 14 or carrier element, which is represented in FIG. 3. The carrier element 14 incorporates locators 15 for energy storage cells 36, locators 16 for reinforcement elements 20 (see FIG. 1b, FIG. 1c, FIG. 4), cut-outs 17 for insulating webs, which can generated in the third production step according to FIG. 1c, line-shaped material recesses 18 for bends, which form bending edges for the folding of the planar assembly 5 in the fourth production step according to FIG. 1d, and insulating coverings 19 for regions which are bridged by conductor track sections. In the second production step according to FIG. 1b, reinforcement elements 20 can be introduced into the carrier 14, as a result of which any separate configuration of locators 16 for reinforcement elements 20 can be omitted. The carrier 14, as represented in FIG. 4, can also incorporate latching elements 21, by way of which force transmission elements 22 in the carrier 14 and/or energy storage cells 36 in the locators 15 (see FIG. 6) can be secured. By using force transmission elements 22, it is possible for the first cell contacts 10 and the second cell contacts 11 to be configured in the form of pressure contacts with the energy storage cells 36. Alternatively, it is possible for cell contacts 10, 11 to be bonded to the cell by way of a welding or soldering method.

The senseboard 7a, in the embodiment according to FIG. 1d, for example, is configured in the form of a rigid-flex PCB, and incorporates flexible regions for the unfolding of the senseboard 7a during the fitting thereof to the cell-contacting system 6 and, as represented in FIG. 1d, contact regions 23 for external contact-connection, for the contact-connection of the conductive pattern 3, and for additional sensor devices 24 of the energy storage cells 36 such as, for example, temperature sensors. The senseboard 7a can moreover comprise connective conductor tracks and guide elements 25 for the prepared contacts 13. The senseboard 7a can also be electrically connected by pressure contacts 26 or metallurgical bonds 27 to the functional conductive pattern 3 and the additional sensor devices 24. The senseboard 7a can also incorporate cut-outs 29 in the region of degassing openings 28 of the energy storage cells 36, in order to permit the unimpeded evacuation of gases from the energy storage cells 36 in the event of degassing.

In the exemplary assembly, the cell-contacting system 6 is connected by the carrier 14 and by the reinforcement elements 20 to a first housing part 30 and a second housing part 31 of a store housing 32 of the electrical energy store EES. In this case, the second housing part 31 is configured with a double-walled design, and forms a cooling duct 34 for the conduction of a coolant. One of the inner sides 33 of the second housing part 31 which faces the energy storage cells 36, is provided with an electrical insulation 35.

The energy storage cells 36 contained in the carrier 14 are also connected to the second housing part 31 in a mechanical and an effective thermally conductive manner. The energy storage cells 36 have a cell housing 37 with a cell housing cover 38 and an electrically insulating cell seal 39. In the cell housing 37, an active cell component 40 is arranged, i.e. a galvanic element. In the case, the cell housing cover 38 incorporates a cell rupture membrane 41 for the coverage of the degassing opening 28.

The first cell contact 10, the force transmission element 22, the senseboard 7a and the first housing part 30 are configured such that the cell rupture membrane 41, in the event of an overpressure in the respective cell housing 37, can open in an unimpeded manner, thus permitting the degassing of the respective energy storage cells 36. To this end, in this case, the first housing part 30 incorporates housing rupture membranes 42 which also open, in the event of the degassing of the locally associated energy storage cells 36. In the region of the cell terminals of the energy storage cells 36, which are electrically connected to the cell contacts 10, 11, the additional sensor devices 24 and the senseboard 7, a flexible electrically insulating material 43 is applied.

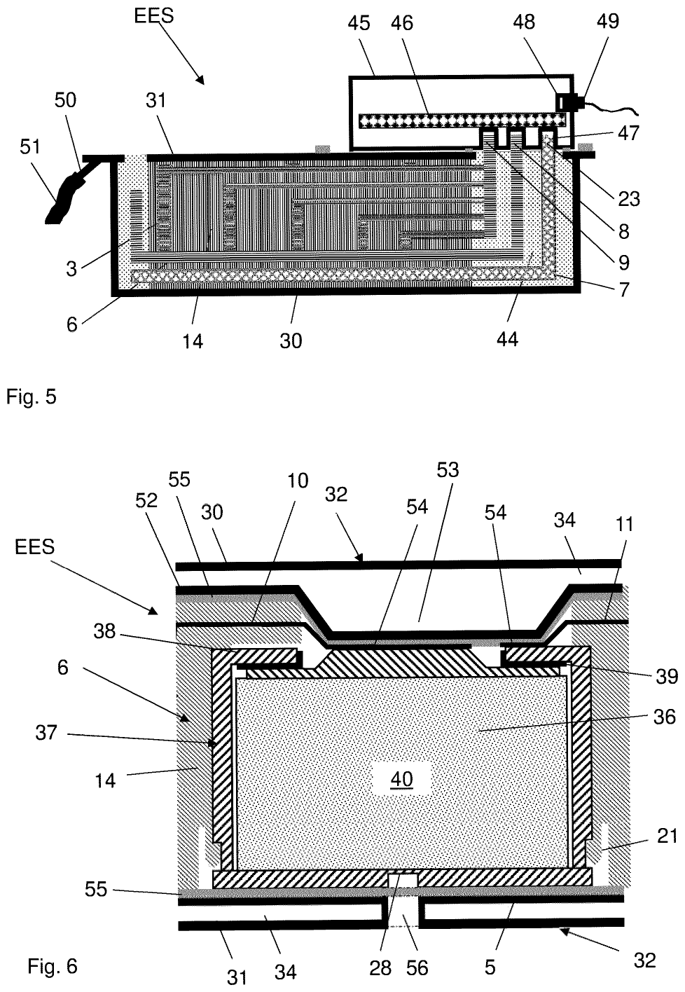

The power terminals 8 and the measuring terminals of the cell-contacting system 6, together with terminals 23 for the external contact-connection of the senseboard 7a, as per the representation of the electrical energy store EES in FIG. 5, are led through openings in the second housing part 31. Around the cell-contacting system 6, the residual interior space of the housing between the first housing part 30 and the second housing part 31 is filled with an electrically insulating material 44. Store electronics 45 of the electrical energy store EES are fitted to the second housing part 31. An electronic circuit 46 of the store electronics 45 incorporates mating contacts 47 for the power terminals 8 and the sensor terminals 9 of the cell-contacting system 6, terminals 23 for the external contact-connection of the senseboard 7a, and external contacts 48 of the electrical energy store EES for connection to an external, off-store electric circuit 49. The second housing part 31 contains terminals 50 for connection to an external, off-store cooling system 51.

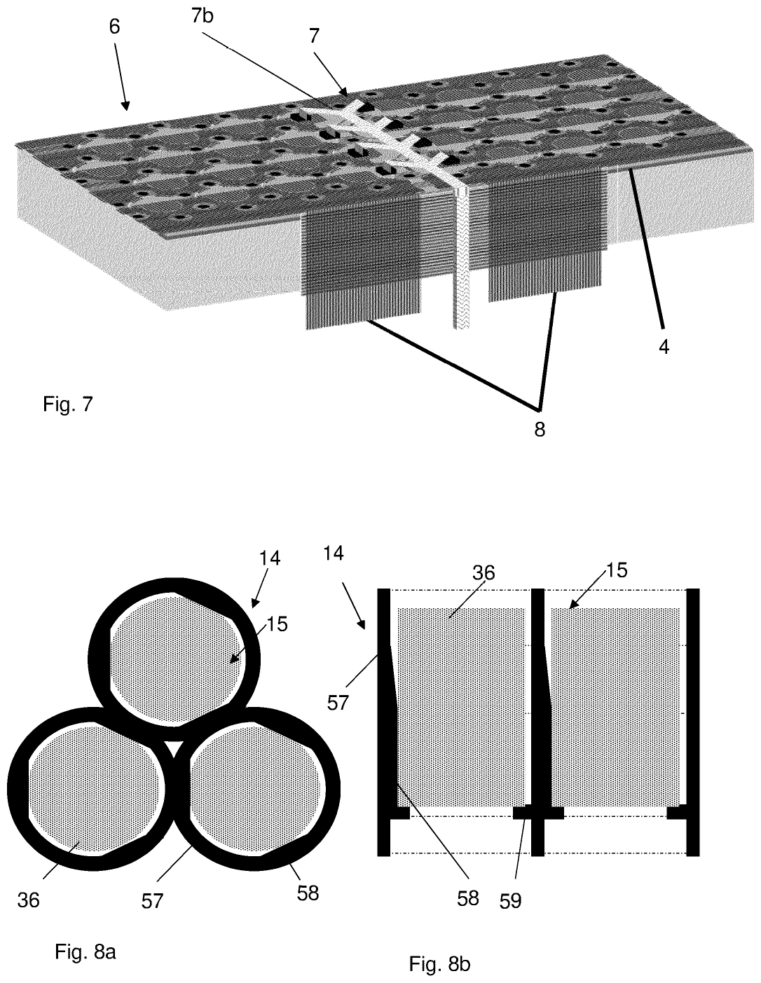

FIG. 6 shows a further embodiment of the electrical energy store 1. In this case, the first housing part 30 is also configured with a double-walled design, and also forms a cooling duct 34 for the conduction of a coolant. By way the double-walled design of the two housing parts 30, 31, the energy storage cells 36 can be cooled on both sides. Moreover, one of the sides 52 facing the cell-contacting system 6 comprises at least one camber 53, which compresses the cell contacts 10, 11 against cell terminals of the energy storage cells 36 which, in this case, are located in the region of the cell housing cover 38. The first housing part 30 is thus employed as an anvil, i.e. the outline of the first housing part 30, in the region of planar contact surfaces 54 of the cell contacts, forms compressive surfaces with a specific degree of elasticity. On the second side, an insulating surface 55 is arranged. In this case, moreover, the second housing part 31 comprises openings 56 which are arranged flush to the degassing openings 28, and via which hot gas can be evacuated from the interior space of the store housing 32 to a surrounding environment. FIG. 7 shows a further configuration of the monitoring device 7, which is configured here in the form of a molding 7b. The molding 7b forms a wave guide for the conduction of acoustic and/or optical signals. The molding 7b can be partially formed of plastic. The sensor devices 24 employed for the monitoring of the electrical energy store EES can be fitted to the first cell contacts 10, the second cell contacts 11, the connections thereof, the carrier 14 or the energy storage cells 36.

FIG. 8a and FIG. 8b show a sectional representation of the carrier 14 in the region of the locators 15 for the energy storage cells 36. In wall regions 57, which form the locators 15, localized thickenings 58 are configured, by way which the energy storage cells 36 are securely clamped in the locators. The locators 15 moreover comprise bracing elements 59 for bracing the energy storage cells 36 in the locators 15.

1.-14. (canceled)

15. A method for producing a cell-contacting system for a cell assembly of energy storage cells of an electrical energy store, the method comprising:
forming a first part of a conductive pattern for interconnection of the energy storage cells by structuring of a conductive material, wherein the structuring comprises extraction of cut-outs from the conductive material;
integrating the structured conductive material in an electrically insulating carrier by joining, which is achieved by primary forming of an insulating material, wherein the insulating material, for a purpose of mechanically connecting conductor tracks of the conductive pattern, is arranged at least locally in the cut-outs, and wherein access openings are formed in the insulating material for exposure of conductor track sections serving as cell contacts, and for configuration of at least one second part of the conductive pattern; and
forming the at least one second part of the conductive pattern by further structuring of the conductive material, wherein further cut-outs are extracted from the conductive material via the access openings in the insulating material.

16. The method according to claim 15,
wherein the cut-outs are extracted from the conductive material by stamping.

17. The method according to claim 15,
wherein the structured conductive material, for joining by primary forming, is at least one of over-molded or embedded in the insulating material.

18. The method according to claim 15,
wherein during the primary forming of the insulating material, at least one of locators for the energy storage cells, locators for reinforcement elements, insulating coverings for conductor track sections, or latching elements of the carrier are produced.

19. The method according to claim 15,
wherein by the structuring of the conductive material, conductor track sections are produced at least one of: in a form of power terminals for contact-connection of the cell assembly, in a form of sensor terminals for contact-connection of sensor devices of the electrical energy store, in a form of cell connectors for connection of cell contacts, as tapers for formation of a fusible link, or in a form of pin-type contact elements which are connected to the cell contacts.

20. The method according to claim 15,
wherein the conductor track sections which form the cell contacts emanate from the carrier in a stepped arrangement, and form a planar, leaf spring-like contact surface.

21. The method according to claim 15,
wherein at least one bending edge is configured in the carrier such that, during the primary forming of the insulating material, line-shaped material recesses are formed in the carrier wherein, by way of the at least one bending edge, at least one edge region of the cell-contacting system is folded to form a frame which at least partially encloses the cell assembly.

22. An electrical energy store comprising:
the cell assembly of energy storage cells,
a store housing, and
the cell-contacting system, wherein:
the cell-contacting system is produced by the method according to claim 15,
the cell assembly and the cell-contacting system are arranged in an interior housing space of the store housing, and
the cell contacts are electrically connected to cell terminals of the energy storage cells.

23. The electrical energy store according to claim 22,
wherein a housing part which faces the cell-contracting system comprises at least one camber, which is configured to compress the cell contacts against the cell terminals of the energy storage cells.

24. The electrical energy store according to claim 22,
wherein a first housing part in a form of a housing cover and a second housing part in a form of a housing base of the store housing are configured with a double-walled design, for conduction of a coolant.

25. The electrical energy store according to claim 22, further comprising:
a monitoring device, which is arranged on the carrier on a side of the cell-contacting system which is averted from the cell assembly and which is configured, for monitoring of the energy storage cells, to transmit signals between sensor devices of the energy storage cells and at least one control device of the electrical energy store.

26. The electrical energy store according to claim 25, wherein:
the monitoring device comprises a waveguide for the transmission of at least one of acoustic or optical signals, and
the waveguide is configured in a form of a molding.

27. The electrical energy store according to claim 25,
wherein a side of the monitoring device which faces the cell-contacting system comprises guide elements for pressure contact pins, for compression of the cell contacts against the cell terminals.

28. A motor vehicle comprising the electrical energy store according to claim 22.
